(19) United States
(12) Patent Application Publication
(10) Pub. No.: US 2005/0012024 A1
(43) Pub. Date: Jan. 20, 2005

(54) Image sensor module and method for manufacturing the same

(76) Inventors: Jackson Hsieh, Hsinchu Hsien (TW); Jichen Wu, Hsinshu Hsien (TW); Abnet Chen, Hsinchu Hsien (TW)

Correspondence Address: Keith Kline;PRO-TECHTOR INTERNATIONAL SERVICES, 20775 Norada Court, Saratoga, CA, 95070-3018, US

(21) Appl. No.: 10/621,985

(22) Filed: Jul. 16, 2003

(51) Int. Cl. H01L 27/00; H01L 31/00

(52) U.S. Cl. 250/208.1; 250/214.1

(57) ABSTRACT

An image sensor module includes an image sensor, and a lens holder and a lens barrel on the image sensor. The image sensor includes plural lower metal sheets, plural upper metal sheets stacked on the lower metal sheets, and an encapsulant for encapsulating the lower and upper metal sheets, wherein the upper surfaces of the upper metal sheets are exposed from the encapsulant, the lower surfaces of the lower metal sheets are exposed from the encapsulant, and the encapsulant is formed with a frame layer around the upper surfaces of the upper metal sheets to define a chamber together with the upper metal sheets. The image sensor further includes a photosensitive chip arranged within the chamber, plural wires for electrically connecting the chip to the upper surfaces of the upper metal sheets, and a transparent layer arranged on the frame layer to cover the chip.

### BACKGROUND OF THE INVENTION

1. Field of the Invention

The invention relates to an image sensor module and a method for manufacturing the same, and more particularly to an image sensor module and a method for manufacturing the same with increased product reliability and facilitated manufacturing processes.

2. Description of the Related Art

Referring to FIG. 1, which is a cross-sectional view showing an image sensor disclosed in a commonly-assigned, copending U.S. patent application Ser. No. 10/146,997, filed on May 15, 2002. The image sensor 1 includes a substrate 10, a frame layer 18, a photosensitive chip 22, a plurality of wires 24, and a transparent layer 27. The substrate 10 is composed of a plurality of metal sheets 12 arranged in an array. Each of the metal sheets 12 has a first board 14 and a second board 16 at different levels. The frame layer 18 is formed at a periphery and a bottom surface of the substrate 10 to form a chamber 20 together with the substrate 10. Top surfaces of the first boards 14 and bottom surfaces of the second boards 16 are exposed from the frame layer 18. The photosensitive chip 22 is arranged within the chamber 20 defined by the frame layer 18 and the substrate 10. The wires 24 electrically connect the top surfaces of the first boards 14 of the metal sheets 12 to the photosensitive chip 22. The transparent layer 27 is arranged on the frame layer 18 to cover the photosensitive chip 22.

Referring to FIG. 2, an image sensor module includes a lens holder 24, a lens barrel 34, and the image sensor 1. The lens holder 24 has a top face 26, a bottom face 28, and a chamber 30 penetrating through the lens holder 24 from the top face 26 to the bottom face 28. The lens holder 24 is formed with an internal thread 32 in the chamber 30. The lens barrel 34 is formed with an external thread 36 and is screwed to the internal thread 32 of the lens holder 24 from the top face 26 of the lens holder 24 and located in the chamber 30. The lens barrel 34 has a transparent region 38, an aspheric lens 40, and an infrared filter 42. The transparent layer 27 of the image sensor 1 is adhered to the bottom face 28 of the lens holder 24. The focal length between the image sensor 1 and the aspheric lens 40 of the lens barrel 34 may be controlled by adjusting the screwed length between the lens barrel 34 and the lens holder 24.

However, the above-mentioned structure has the following drawbacks.
1. Since the metal sheets 12 are bent to form the first boards 14 and second boards 16 at different levels, the formed first boards 14 may be uneven. Therefore, the wires 24 cannot be conveniently bonded to the metal sheets 12, and the yield may be influenced.
2. Since the thickness of each of the second boards 16 of the metal sheets 12 is thinner (because each metal sheet 12 with greater thickness cannot be pressed during the manufacturing processes), the solder tin cannot climb to the lateral side of each metal sheet 12 during the SMT process. Therefore, the package body cannot be mounted to the printed circuit board with great stability.

### SUMMARY OF THE INVENTION

An object of the invention is to provide an image sensor module with increased thickness of the combined metal sheets, and a method for manufacturing the same with improved package reliability.

Another object of the invention is to provide an image sensor module and a method for manufacturing the same, wherein the solder tin may climb higher during the SMT process and the image sensor may be mounted to the printed circuit board with great stability.

Still another object of the invention is to provide an image sensor module and a method for manufacturing the same, wherein the wire bonding process may be easily performed and the product yield may be increased.

To achieve the above-mentioned objects, the invention provides an image sensor module to be electrically connected to a printed circuit board. The image sensor module includes a plurality of lower metal sheets arranged in an array, a plurality of upper metal sheets arranged in an array, an encapsulant for encapsulating the lower metal sheets and the upper metal sheets, a photosensitive chip, a plurality of wires, a transparent layer, a lens holder and a lens barrel. Each of the lower metal sheets has an upper surface and a lower surface. Each of the upper metal sheets has an upper surface and a lower surface. The lower surfaces of the upper metal sheets are stacked on the upper surfaces of the lower metal sheets. The upper surfaces of the upper metal sheets are exposed from the encapsulant, and the lower surfaces of the lower metal sheets are exposed from the encapsulant and electrically connected to the printed circuit board. The encapsulant is formed with a frame layer around the upper surfaces of the upper metal sheets to define a chamber together with the upper metal sheets. The photosensitive chip is arranged within the chamber. The wires electrically connect the photosensitive chip to the upper surfaces of the upper metal sheets. The transparent layer is arranged on the frame layer of the encapsulant to cover the photosensitive chip. The lens holder is formed with a chamber penetrating through the lens holder and an internal thread at a periphery of the chamber. The frame layer is fixed to the lens holder so that the transparent layer is located at a side of the chamber. The lens barrel is arranged within the chamber of the lens holder. The lens barrel is formed with an external thread screwed to the internal thread of the lens holder. The lens barrel is formed with a chamber penetrating through the lens barrel and has a transparent region and an aspheric lens in the chamber from top to bottom.

### BRIEF DESCRIPTION OF THE DRAWINGS

FIG. 1 is a cross-sectional view showing an image sensor disclosed in a commonly-assigned, copending U.S. patent application Ser. No. 10/146,997, filed on May 15, 2002.

FIG. 2 is a schematic illustration showing the module structure of FIG. 1.

FIG. 3 is a cross-sectional view showing an image sensor module of the invention.

FIG. 4 is a first schematic illustration showing a method for manufacturing the image sensor module of the invention.

FIG. 5 is a second schematic illustration showing the method for manufacturing the image sensor module of the invention.

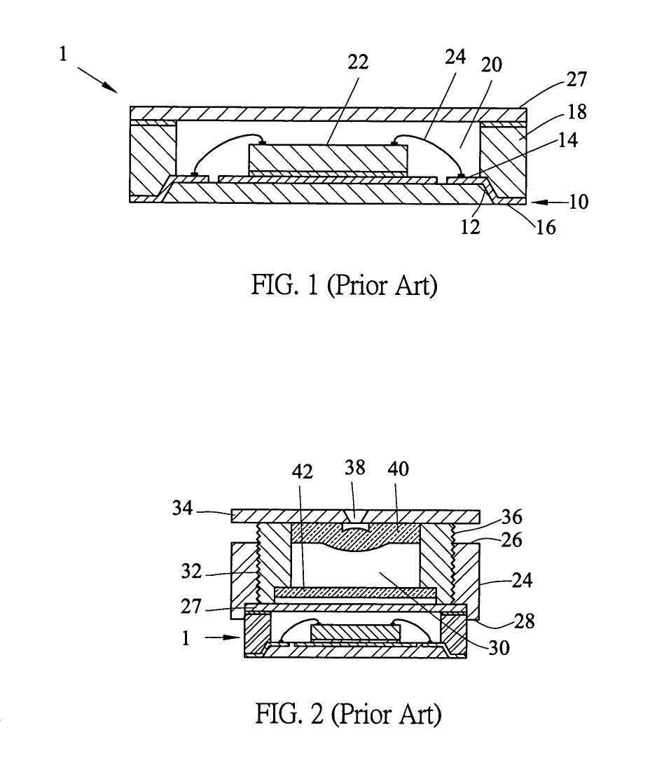

### DETAILED DESCRIPTION OF THE INVENTION

Referring to FIG. 3, an image sensor module of the invention includes a plurality of lower metal sheets 50 arranged in an array, a plurality of upper metal sheets 52 arranged in an array, an encapsulant 54, a photosensitive chip 56, a plurality of wires 58, a transparent layer 60, a lens holder 62, and a lens barrel 64.

Each lower metal sheet 50 has an upper surface 66 and a lower surface 68 mounted to a printed circuit board 70 via solder tin 94 in the SMT process.

Each upper metal sheet 52 has an upper surface 72 and a lower surface 74. A middle board 76 flush with the upper metal sheets 52 is arranged among the upper metal sheets 52. The lower surfaces 74 are stacked on the corresponding upper surfaces 66 of the lower metal sheets 50.

The encapsulant 54 encapsulates the lower metal sheets 50, the upper metal sheets 52 and the middle board 76 with the upper surfaces 72 of the upper metal sheets 52 and an upper surface of the middle board 76 exposed from the encapsulant 54 and with the lower surfaces 68 of the lower metal sheets 50 exposed from the encapsulant 54. A frame layer 78 is formed around the upper surfaces 72 of the upper metal sheets 52 to define a chamber 80 together with the upper metal sheets 52.

The photosensitive chip 56 is arranged on the middle board 76 and located within the chamber 80.

The plurality of wires 58 electrically connect the photosensitive chip 56 to the upper surfaces 72 of the upper metal sheets 52 so as to transfer signals from the photosensitive chip 56 to the upper metal sheets 52.

The transparent layer 60 is a piece of transparent glass arranged on the frame layer 78 of the encapsulant 54 to cover the photosensitive chip 56. Thus, the photosensitive chip 56 may receive optical signals passing through the transparent layer 60.

The lens holder 62 is formed with a chamber 82 penetrating through the lens holder 62, and an internal thread 84 at the periphery of the chamber 82. The frame layer 78 is fixed to the lens holder 62 so that the transparent layer 60 is located at a side of the chamber 82.

The lens barrel 64 is arranged within the chamber 82 of the lens holder 62 and is formed with an external thread 86 screwed to the internal thread 84 of the lens holder 62. The lens barrel 64 is formed with a chamber 87 penetrating through the lens barrel 64 and has a transparent region 88, an aspheric lens 90 and an infrared filter 92 in the chamber 87 from top to bottom. Consequently, the above-mentioned objects and effects may be achieved.

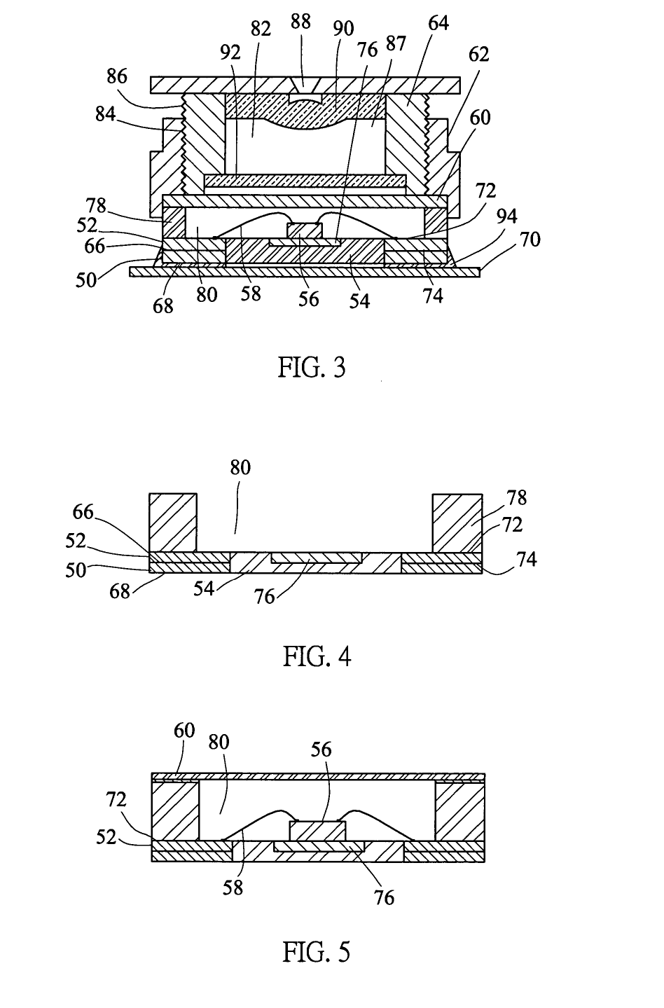

Referring to FIG. 4, a method for manufacturing an image sensor module of the invention includes the steps of:
providing a plurality of lower metal sheets 50 arranged in an array, each of the lower metal sheets 50 having an upper surface 66 and a lower surface 68;
providing a plurality of upper metal sheets 52 arranged in an array, each of the upper metal sheets 52 having an upper surface 72 and a lower surface 74, and providing a middle board 76 arranged among and flush with the upper metal sheets 52, the lower surfaces 74 being stacked on the upper surfaces 66 of the lower metal sheets 50; and
encapsulating the lower metal sheets 50, the upper metal sheets 52 and the middle board 76 using industrial plastic material by way of injection molding, wherein the upper surfaces 72 of the upper metal sheets 52 and an upper surface of the middle board 76 are exposed from the encapsulant 54 and the lower surfaces 68 of the lower metal sheets 50 are exposed from the encapsulant 54, and forming a frame layer 78 around the upper surfaces 72 of the upper metal sheets 52 to define a chamber 80 together with the upper metal sheets 52.

Referring to FIG. 5, the method for forming the image sensor module of the invention further includes the steps of:
mounting a photosensitive chip 56 to the middle board 76 and within the chamber 80;
providing a plurality of wires 58 to electrically connect the photosensitive chip 56 to the upper surfaces 72 of the upper metal sheets 52 so as to transfer signals from the photosensitive chip 56 to the upper metal sheets 52; and
arranging a transparent layer 60, which is a piece of transparent glass, on the frame layer 78 of the encapsulant 54 to cover the photosensitive chip 56 so that the photosensitive chip 56 may receive optical signals passing through the transparent layer 60.

Referring to FIGS. 5 and 3, the method for forming the image sensor module of the invention further includes the steps of:
providing a lens holder 62 formed with a chamber 82 penetrating through the lens holder 62, and an internal thread 84 at the periphery of the chamber 82, wherein the frame layer 78 is fixed to the lens holder 62 so that the transparent layer 60 is located at a side of the chamber 82.
arranging a lens barrel 64, which is formed with an external thread 86 screwed to the internal thread 84 of the lens holder 62, within the chamber 82 of the lens holder 62, wherein the lens barrel 64 is formed with a chamber 87 penetrating through the lens barrel 64 and has a transparent region 88, an aspheric lens 90 and an infrared filter 92 in the chamber 87 from top to bottom.

Consequently, the above-mentioned objects and effects may be achieved.

The invention has the following advantages.
1. Since the upper and lower metal sheets 52 and 50 are formed from two flat boards, better smoothness may be obtained. Consequently, the wire bonding process may be easily performed, and the package yield of the product may be improved.
2. Since the combination of the upper and lower metal sheets 52 and 50 is thicker, the solder tin 94 may climb to the upper metal sheets 52 from the lower metal sheets 50 during the SMT process for mounting the image sensor module to the printed circuit board 70. Therefore, the package body can be mounted to the printed circuit board 70 with great stability.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. An image sensor module to be electrically connected to a printed circuit board, the image sensor module comprising:
a plurality of lower metal sheets arranged in an array, each of the lower metal sheets having an upper surface and a lower surface;
a plurality of upper metal sheets arranged in an array, each of the upper metal sheets having an upper surface and a lower surface, the lower surfaces of the upper metal sheets being stacked on the upper surfaces of the lower metal sheets;
an encapsulant for encapsulating the lower metal sheets and the upper metal sheets, wherein the upper surfaces of the upper metal sheets are exposed from the encapsulant, the lower surfaces of the lower metal sheets are exposed from the encapsulant and electrically connected to the printed circuit board, and the encapsulant is formed with a frame layer around the upper surfaces of the upper metal sheets to define a chamber together with the upper metal sheets;
a photosensitive chip arranged within the chamber;
a plurality of wires for electrically connecting the photosensitive chip to the upper surfaces of the upper metal sheets;
a transparent layer arranged on the frame layer of the encapsulant to cover the photosensitive chip;
a lens holder formed with a chamber penetrating through the lens holder and an internal thread at a periphery of the chamber, the frame layer being fixed to the lens holder so that the transparent layer is located at a side of the chamber; and
a lens barrel arranged within the chamber of the lens holder, the lens barrel being formed with an external thread screwed to the internal thread of the lens holder, wherein the lens barrel is formed with a chamber penetrating through the lens barrel and has a transparent region and an aspheric lens in the chamber from top to bottom.

2. The image sensor module according to claim 1, further comprising a middle board arranged among and flush with the upper metal sheets, and the photosensitive chip being mounted to the middle board.

3. The image sensor module according to claim 1, wherein the encapsulant is made of industrial plastic material, and the encapsulant and the frame layer are integrally formed.

4. The image sensor module according to claim 1, wherein the transparent layer is a piece of transparent glass.

5. The image sensor module according to claim 1, wherein the lens barrel further has an infrared filter under the aspheric lens in the chamber.

6. A method for manufacturing an image sensor module, comprising the steps of:
providing a plurality of lower metal sheets arranged in an array, each of the lower metal sheets having an upper surface and a lower surface;
providing a plurality of upper metal sheets arranged in an array, each of the upper metal sheets having an upper surface and a lower surface, the lower surfaces of the upper metal sheets being stacked on the upper surfaces of the lower metal sheets;
providing an encapsulant for encapsulating the lower metal sheets and the upper metal sheets, wherein the upper surfaces of the upper metal sheets are exposed from the encapsulant, the lower surfaces of the lower metal sheets are exposed from the encapsulant and electrically connected to a printed circuit board, and the encapsulant is formed with a frame layer around the upper surfaces of the upper metal sheets to define a chamber together with the upper metal sheets;
arranging a photosensitive chip within the chamber;
arranging a transparent layer on the frame layer of the encapsulant to cover the photosensitive chip;
providing a lens holder formed with a chamber penetrating through the lens holder and an internal thread at a periphery of the chamber, the frame layer being fixed to the lens holder so that the transparent layer is located at a side of the chamber; and
arranging a lens barrel within the chamber of the lens holder, the lens barrel being formed with an external thread screwed to the internal thread of the lens holder, wherein the lens barrel is formed with a chamber penetrating through the lens barrel and has a transparent region and an aspheric lens in the chamber from top to bottom.

7. The method according to claim 6, further comprising:
arranging a middle board among and flush with the upper metal sheets, and the photosensitive chip being mounted to the middle board.

8. The method according to claim 6, wherein the encapsulant and the frame layer are formed from industrial plastic material by way of injection molding.

9. The method according to claim 6, wherein the lens barrel further has an infrared filter under the aspheric lens in the chamber.
